(19) United States
(12) Patent Application Publication
(10) Pub. No.: US 2008/0102626 A1
(43) Pub. Date: May 1, 2008

(54) METHOD OF FORMING COPPER WIRING IN SEMICONDUCTOR DEVICE

(76) Inventors: Cheol Hwi RYU, Kyoungki-do (KR); Hyung Soon PARK, Kyoungki-do (KR); Jong Han SHIN, Seoul (KR); Jum Yong PARK, Kyoungki-do (KR); Sung Jun KIM, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/776,066

(22) Filed: Jul. 11, 2007

(30) Foreign Application Priority Data
Oct. 31, 2006 (KR) 10-2006-0106908

(51) Int. Cl. H01L 21/4763

(52) U.S. Cl. 438/643; 257/E21.495

(57) ABSTRACT

A semiconductor package includes method of forming a copper wiring may comprise forming an interlayer insulation film provided with a damascene pattern for wiring over a semiconductor substrate; depositing a barrier metal film over a surface of the damascene pattern and the interlayer insulation film; depositing a copper film over the barrier metal film so as to fill the damascene pattern; and performing an electrochemical mechanical polishing by using a fixed-abrasive pad, supplying an electrolyte solution, and applying an electric field so as to expose the interlayer insulation film.

### CROSS-REFERENCE TO RELATED APPLICATIONS

The present application claims priority to Korean patent application number 10-2006-0106908 filed on Oct. 31, 2006, which is incorporated herein by reference in its entirety.

### BACKGROUND OF THE INVENTION

The present invention relates to a method of forming a copper wiring in a semiconductor device, and more particularly to a method of forming a copper wiring capable of preventing a reduction in a polishing speed and a reduction in a polish uniformity.

Because it is difficult to etch copper by a conventional etching process, a damascene process is generally used to form a copper wiring. Hereinafter, a conventional method of forming a copper wiring using the damascene process will be briefly described.

After an interlayer insulation film is formed over an upper portion of a semiconductor substrate, the interlayer insulation film is etched to form a damascene pattern consisting of a hole or a hole and a trench for wiring. After a barrier metal film is deposited over the surface of the damascene pattern and the interlayer insulation film in order to prevent a copper diffusion, a copper film is formed so as to fill the damascene pattern. After a first chemical mechanical polishing (CMP) process is performed to the copper film, a second CMP process is performed to the barrier metal film so as to expose the interlayer insulation film, thereby forming a copper wiring in the damascene pattern.

Herein, the CMP process is a planarization process in which chemical reaction due to slurry and mechanical processing by a polishing pad are performed simultaneously. This aspect of CMP process is considered more advantageous as it can be performed at a lower temperature to attain a global planarization than the reflow and etch back process performed for surface planarization.

When forming a copper wiring using the damascene process as known conventionally, disadvantages exist in that separate CMP processes are required for polishing the copper and polishing the barrier metal film, thereby increasing the complexity of the process and the cost involved. In addition, because the CMP process is performed twice, the layers or films on the semiconductor substrate may be unevenly polished and even the layers or films on different substrates undergoing the polishing process may be unevenly polished with respect to other substrates when the conventional method of forming a copper wiring using the damascene process is used.

Further, the conventional method of forming a copper wiring using the damascene process has a disadvantage in that a dishing of the copper wiring can easily occur as a result of an over polishing for removing copper residue.

Also, in the conventional method of forming a copper wiring using the damascene process, an ultra low pressure polishing is proceeded in order to reduce problems of peeling of the copper and scratches and to minimize mechanical damage of low-k materials used as the interlayer insulation film. However, there is a disadvantage that polishing ununiformity is increased due to the reduction in a polishing speed because the polishing speed is slow in the ultra low pressure polishing.

### BRIEF SUMMARY OF THE INVENTION

Embodiments of the present invention are directed to a method of forming a copper wiring, which is capable of preventing a complication of a process and an increase in process cost.

Further, embodiments of the present invention are directed to a method of forming a copper wiring, which is capable of preventing a reduction in a polishing uniformity.

Also, embodiments of the present invention are directed to a method of forming a copper wiring, which is capable of preventing occurrence of a dishing.

In addition, embodiments of the present invention are directed to a method of forming a copper wiring, which is capable of preventing reduction in a polishing speed.

In one embodiment, a method of forming a copper wiring may comprise forming an interlayer insulation film provided with a damascene pattern for wiring over a semiconductor substrate; depositing a barrier metal film over a surface of the damascene pattern and the interlayer insulation film; depositing a copper film over the barrier metal film so as to fill the damascene pattern; and performing an electrochemical mechanical polishing by using a fixed-abrasive pad, supplying an electrolyte solution, and applying an electric field so as to expose the interlayer insulation film.

The barrier metal film made of at least one of Ta, TaN, Ti and TiN.

The electrolyte solution includes one of an abrasive free slurry, an acidic solution, an alkaline solution and an aqueous solution of a salt.

The electrolyte solution is supplied at a flow rate of 10 to 200 ml/min or supplied using an electrochemical bath containing an electrolyte.

The electric field is applied using a potentiostat as an electric field applying apparatus.

The electric field applying using the potentiostat is performed by connecting a working electrode to the copper film or the barrier metal film and connecting a reference electrode and a counter electrode to the electrolyte solution.

The electric field applying is performed by maintaining a potential difference to a range of −2 to +4V and adjusting a potential to an electrostatic potential or 1 to 1000 mV/sec.

The electric field applying is performed by maintaining a potential difference to a range of −2 to +4V and adjusting a current density to 1 to 1000 mA/cm³.

The reference electrode is formed of a material including one of Ag/AgCl, saturated calomel, Cu/CUSO₄, Hg/HgSO₄ and Hg/HgO.

The counter electrode may be formed of a noble metal including one of Pt, Ru, and Ir.

The counter electrode may be formed of a carbon material includes one of a graphite plate, a graphite felt and a carbon felt.

The electrochemical mechanical polishing is performed at a polishing pressure of 0.1 to 10 psi and a polishing table speed of 10 to 100 rpm.

### BRIEF DESCRIPTION OF THE DRAWINGS

FIGS. 1A through 1D are cross-sectional views illustrating the process steps of a method of forming a copper wiring in accordance with an embodiment of the present invention.

FIG. 2 is a cross-sectional view illustrating an electrochemical mechanical polishing process in the method of forming a copper wiring in accordance with an embodiment of the present invention.

FIG. 3 is a graph illustrating potential of copper oxidation reaction in the method of forming a copper wiring in accordance with an embodiment of the present invention.

### DESCRIPTION OF SPECIFIC EMBODIMENTS

A preferred embodiment of the present invention is directed to a method of forming a copper wiring, in which a polishing for a copper film and a barrier metal film is performed in an electrochemical mechanical polishing which applies an electric field while supplying abrasive free slurry on a fixed-abrasive pad in which the abrasive particles are fixedly bonded to a pad.

Therefore, in an embodiment of the present invention, since the slurry without the abrasive particles is used, an over polishing required to remove slurry residue can be reduced and thus it can be possible to proceed a defect free process capable of restricting a dishing. Further, in an embodiment of the present invention, because it is not necessary to use another slurry for polishing a barrier metal film after polishing a copper film, it is possible to prevent complication in process and cost increase and, particularly, it is possible to reduce polishing ununiformity since it is possible to polish both the copper film and the barrier metal film by performing only one time of polishing process.

Also, in an embodiment of the present invention, because an electrochemical oxidation of copper is promoted by applying an electric field, a polishing speed is increased further, and thus it is possible to improve a reduction in the polishing uniformity, which is a problem in a conventional ultra low pressure polishing process. Also, it is possible to control a polishing speed by applying electrochemical mechanical polishing techniques utilizing the electrostatic potential, the potential sweep, and a constant current, and thus it is possible to minimize dishing thereby improving the reliability of a device.

Meanwhile, the polishing speed may be reduced in the case of using the slurry without the abrasive particles; however, in an embodiment of the present invention, the reduction in the polishing speed is prevented even using the slurry without the abrasive particles since the fixed-abrasive pad is used.

Hereafter, a method of forming a copper wiring in accordance with an embodiment of the present invention will be described with reference to the attached drawings.

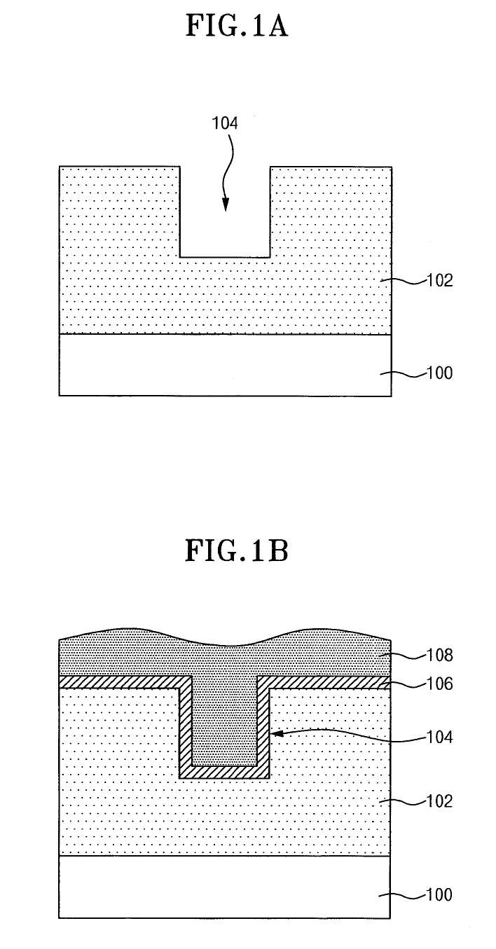

Referring to FIG. 1A, an interlayer insulation film 102 made of a low-k material is formed over a semiconductor substrate 100 provided with a base structure, and then the interlayer insulation film 102 is etched to form a damascene pattern 104. The damascene pattern 104 consists of a hole or a hole and a trench.

Referring to FIG. 1B, a barrier metal film 106 formed of one of Ta, Ti, TaN, and TiN is deposited by a CVD or PVD process over the interlayer insulation film 102 including a surface of the damascene pattern 104, and then a copper film 108 is deposited by a CVD or PVD process over the barrier metal film 106 so as to fill the damascene pattern 104.

Referring to FIG. 1C, the copper film 108 is polished to expose a portion of the barrier metal film 106 formed over the interlayer insulation film 102 by performing an electrochemical mechanical polishing process in which an electric field is applied to the semiconductor substrate 100 deposited with the copper film 108.

Referring to FIG. 1D, a copper wiring 110 is formed by performing an electrochemical mechanical polishing process to remove the barrier metal film 106 so as to expose the interlayer insulation film 102 while the electric field is still applied.

The process for polishing the copper film 108 and the barrier metal film 106 is performed using a fixed-abrasive pad to which abrasive particles are fixedly bonded and using an abrasive free slurry as an electrolyte solution. The process for polishing the copper film 108 and the barrier metal film 106 is performed in an electrochemical mechanical polishing process by applying an electric field. As an electrolyte solution, it may be possible to use one of the acidic solution, the alkaline solution, and the aqueous solution of a salt instead of the abrasive free slurry. The electrolyte solution of the abrasive free slurry, the acidic solution, the alkaline solution or the aqueous solution of a salt is supplied at 10 to 200 ml/min or is supplied using an electrochemical bath containing an electrolyte.

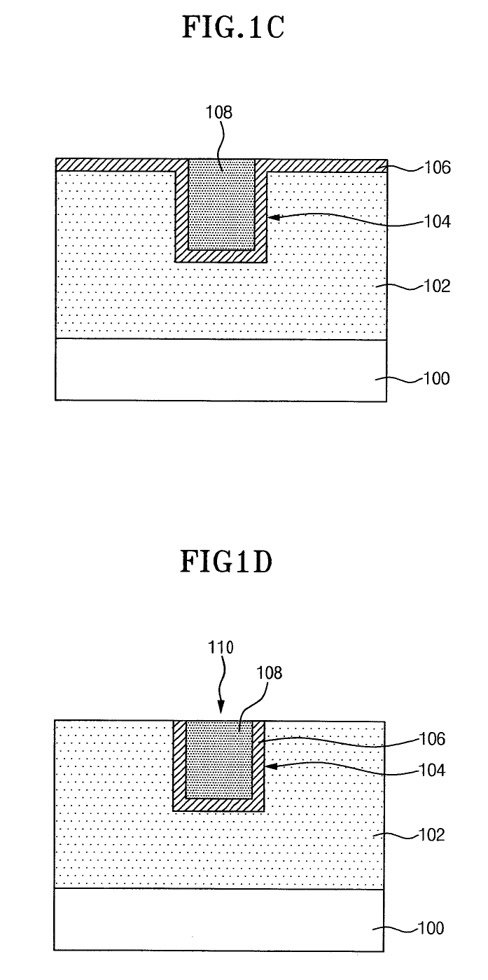

FIG. 2 is a cross-sectional view illustrating the electrochemical mechanical polishing process in the method of forming a copper wiring in accordance with an embodiment of the present invention.

As shown, the electrochemical mechanical polishing is performed in a state that the semiconductor substrate 100 formed with the copper film 108 and the barrier metal film 106 is disposed on a fixed-abrasive pad 200, an electrolyte solution 210 such as the abrasive free slurry is supplied to the fixed-abrasive pad 200, and an electric field is applied from an electric field applying apparatus 220 to a structure of the semiconductor substrate 100.

In order to maintain the constant current and electrostatic potential from the electric field applying apparatus 220, a potentiostat can be utiliezed, and an electrostatic potential, an electric sweep, or a constant current method can be used, and an equipment having the three electrodes system having a working electrode 212, a reference electrode 214, and a counter electrode 216. The working electrode 212 is connected to the copper film 108 or the barrier metal film 106, and the reference electrode 214 and the counter electrode 216 are connected to the electrolyte solution.

For example, the electric field applied from the electric field applying apparatus 220 is applied by maintaining a potential difference to a range of −2 to +4V and adjusting a potential to an electrostatic potential or 1 to 1000 mV/sec or by maintaining a potential difference to a range of −2 to +4V and adjusting a current density to 1 to 1000 mA/cm³.

The reference electrode 214 is formed of one of Ag/AgCl, saturated calomel, CU/CUSO₄, Hg/HgSO₄ and Hg/HgO. The counter electrode 216 is formed of noble metal including one of Pt, Ru, and Ir. Further, The counter electrode 216 may be formed of a carbon material including one of a graphite plate, a graphite felt, and a carbon felt.

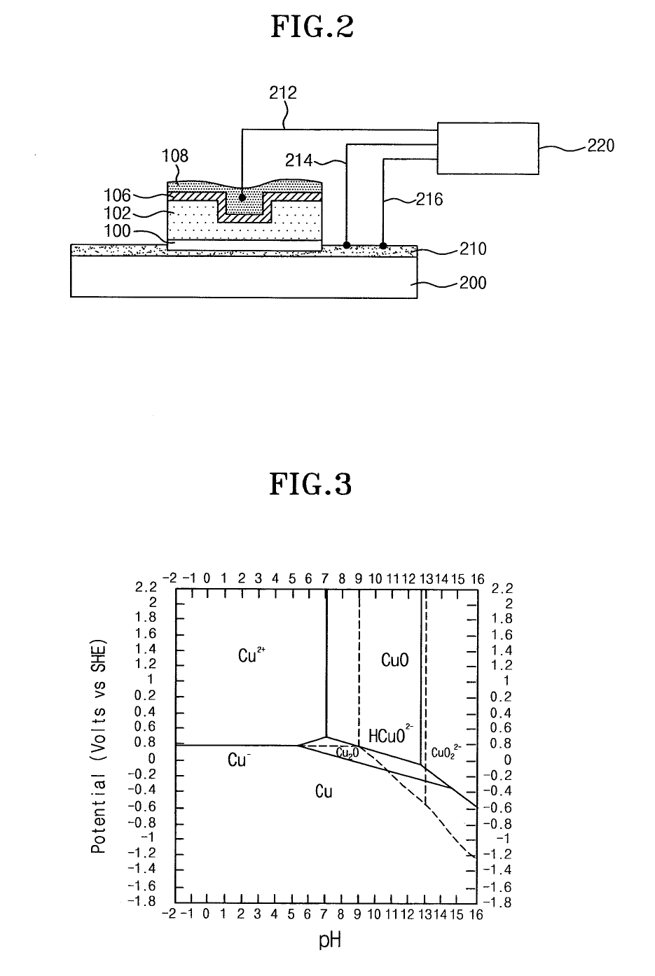

FIG. 3 is a graph illustrating the potential of copper oxidation reaction in the method of forming a copper wiring in accordance with an embodiment of the present invention.

First, an equilibrium dissolution reaction of copper in acidic aqueous solution is as follows:

Cu⇄Cu⁺+e⁻(−2<pH<5) \textcircled{1}

Cu⇄Cu²⁺+2e⁻(−2<pH<5) \textcircled{2}

Cu₂O+2H⁺⇄2Cu²⁺+H₂O+2e⁻(−2<pH<5) \textcircled{3}

Further, the oxidation of copper is proceeded by a reduction reaction of dissolved oxygen.

O₂+2H₂O+2e⁻=2OH⁻ \textcircled{4}

As shown, Cu exists as Cu2+ below pH 4 and thus an increase in the polishing speed can be promoted. However, in a case that pH is in 7 to 12 and a potential is +0.2V versus standard hydrogen electrode, it can be appreciated that it is difficult to polish Cu since Cu exists as a state of a stable oxide of CuO.

Therefore, in accordance with an embodiment of the present invention, when removing the copper film 108 using the electrochemical mechanical polishing process, the polishing speed is maintained high by supplying the electrolyte less than pH 4 and applying the electric field at the initial stage and the polishing speed is maintained low by supplying the electrolyte more than pH 7 and applying an electric field at the last stage. By doing this, it is possible to minimize occurrence of a dishing.

As is apparent from the above description, in an embodiment of the present invention, the polishing of the copper film and the barrier metal film is performed through the electrochemical mechanical polishing process on the fixed-abrasive pad by supplying an electrolyte including one of an abrasive free slurry, an acidic solution, an alkaline solution and an aqueous solution of a salt, and applying an electric field. Accordingly, it is possible to prevent a reduction in a polishing speed as electrochemical oxidation of copper is promoted and thus polishing ununiformity can be reduced.

Also, in an embodiment of the present invention, because it is not necessary to use a separate slurry for polishing the barrier metal film since the polishing of the copper film and the barrier metal film is performed using a single slurry, it is possible to avoid overly complicated processes and the associated cost increase. Particularly, since both the copper film and the barrier metal film can be polished by preferably only one performance of the polishing process as described above, the polishing ununiformity can be reduced.

Although a specific embodiments of the present invention has been described for illustrative purposes, those skilled in the art will appreciate that various modifications, additions and substitutions are possible, without departing from the scope and the spirit of the invention as disclosed in the accompanying claims.

What is claimed is:

1. A method of forming a copper wiring, comprising the steps of:
forming an interlayer insulation film provided with a damascene pattern for wiring over a semiconductor substrate;
depositing a barrier metal film over a surface of the damascene pattern and the interlayer insulation film;
depositing a copper film over the barrier metal film so as to fill the damascene pattern; and
performing an electrochemical mechanical polishing by using a fixed-abrasive pad, supplying an electrolyte solution, and applying an electric field so as to expose the interlayer insulation film.

2. The method of forming a copper wiring according to claim 1, wherein the barrier metal film made of at least one of Ta, Ti, TaN and TiN.

3. The method of forming a copper wiring according to claim 1, wherein the electrolyte solution includes one of an abrasive free slurry, an acidic solution, an alkaline solution, and an aqueous solution of a salt.

4. The method of forming a copper wiring according to claim 1, wherein the electrolyte solution is supplied at a flow rate of 10 to 200 ml/min.

5. The method of forming a copper wiring according to claim 1, wherein the electrolyte solution is supplied using an electrochemical bath containing an electrolyte.

6. The method of forming a copper wiring according to claim 1, wherein the electric field is applied using a potentiostat as an electric field applying apparatus.

7. The method of forming a copper wiring according to claim 6, wherein the electric field is applied using the potentiostat by connecting a working electrode to the copper film or the barrier metal film and connecting a reference electrode and a counter electrode to the electrolyte solution.

8. The method of forming a copper wiring according to claim 7, wherein the electric field is appled by maintaining a potential difference to a range of −2 to +4V and adjusting a potential to an electrostatic potential or 1 to 1000 mV/sec.

9. The method of forming a copper wiring according to claim 7, wherein the electric field is applied by maintaining a potential difference to a range of −2 to +4V and adjusting a current density to 1 to 1000 mA/cm³.

10. The method of forming a copper wiring according to claim 7, wherein the reference electrode is formed of a material including one of Ag/AgCl, saturated calomel, Cu/CuSO₄, Hg/HgSO₄, and Hg/HgO.

11. The method of forming a copper wiring according to claim 7, wherein the counter electrode is formed of a noble metal or a carbon material.

12. The method of forming a copper wiring according to claim 11, wherein the noble metal includes one of Pt, Ru, and Ir.

13. The method of forming a copper wiring according to claim 11, wherein the carbon material includes one of a graphite plate, a graphite felt, and a carbon felt.

14. The method of forming a copper wiring according to claim 1, wherein the electrochemical mechanical polishing is performed at a polishing pressure of 0.1 to 10 psi and a polishing table speed of 10 to 100 rpm.
